(19) United States
(12) Patent Application Publication
(10) Pub. No.: US 2025/0145521 A1
(43) Pub. Date: May 8, 2025

(54) PROCESS FOR FORMING A COATING

(71) Applicant: Pilkington Group Limited, Lathom (GB)

(72) Inventor: Jun NI, Maumee, OH (US)

(21) Appl. No.: 18/865,778

(22) PCT Filed: May 24, 2023
(86) PCT No.: PCT/GB2023/051359

§ 371 Date: Nov. 14, 2024

Related U.S. Application Data
(60) Provisional application No. 63/345,145, filed on May 24, 2022.

(51) Int. Cl. C03C 17/34; C23C 16/40; C23C 16/54

(52) U.S. Cl. CPC C03C 17/3417; C23C 16/406; C23C 16/545; C03C 2217/211; C03C 2217/213; C03C 2217/217; C03C 2218/152

(57) ABSTRACT

A chemical vapor deposition process is provided for forming a layer based on nickel oxide over a glass substrate. A gaseous mixture is formed and includes a nickel-containing compound selected from the group consisting of nickel(II) acetylacetonate and derivatives thereof, and an oxygen-containing precursor selected from the group consisting of a carbonyl compound and molecular oxygen. The gaseous mixture is directed toward and along the glass substrate, and is reacted over the glass substrate to form a nickel oxide coating thereon.

### BACKGROUND

The invention relates in general to a process for forming a coating or layer based on nickel oxide. In particular, the invention relates to a chemical vapor deposition (CVD) process for forming a coating based on nickel oxide over a glass substrate.

### SUMMARY OF THE INVENTION

Embodiments of a chemical vapor deposition process for forming a nickel oxide coating are described below. In an embodiment, the chemical vapor deposition process for forming a nickel oxide coating comprises providing a glass substrate, preferably a moving glass substrate. A gaseous mixture is formed that comprises a nickel containing compound and one or more oxygen-containing precursors. The nickel containing compound is preferably one or more of nickel(II) acetylacetonate and its derivatives. The one or more oxygen-containing precursors are preferably selected from the group consisting of a carbonyl compound and molecular oxygen.

The gaseous mixture is directed toward and along the glass substrate. The gaseous mixture is reacted over the glass substrate to form a nickel oxide coating over the glass substrate.

In some embodiments, the glass substrate is a glass ribbon in a float glass manufacturing process.

In other embodiments, the nickel oxide coating is formed on a deposition surface of the glass substrate which is at essentially atmospheric pressure.

In some embodiments, a coating apparatus is provided and the gaseous mixture is fed through the coating apparatus before forming the nickel oxide coating over the glass substrate.

The nickel oxide coating may be formed on a deposition surface of the glass substrate which is at essentially atmospheric pressure when the gaseous mixture is reacted to form the nickel oxide coating.

There may be embodiments wherein the nickel oxide coating is formed over a coating previously formed on the glass substrate. Thus, in some embodiments, the nickel oxide coating is formed over a coating based on silicon oxide and/or tin oxide previously formed over the glass substrate. In some embodiments, the nickel oxide coating is formed over a transparent conducting oxide (TCO) coating such as fluorine doped tin oxide or indium tin oxide, as examples, previously formed over the glass substrate. In certain preferred embodiments, the TCO is a coating based on tin oxide doped with fluorine. It may be preferred that the nickel oxide coating be deposited over a TCO coating that is deposited over a coating based on silicon oxide that is in turn deposited over the glass substrate. In certain embodiments, the nickel oxide coating is the outermost coating of a coating stack provided on a glass substrate.

In certain embodiments, the glass substrate is at a temperature of between 1000° F. (538° C.) and 1400° F. (760° C.) when the nickel oxide coating is formed thereover and the nickel oxide coating is pyrolytic.

In certain preferred embodiments, the nickel containing compound is one or more of nickel(II) acetylacetonate, bis(2,2,6,6-tetramethyl-3,5-heptanedionato) nickel(II), nickel(II) hexafluoroacetylacetonate, and nickel(II) trifluoroacetylacetonate. Commercially available nickel(II) hexafluoroacetylacetonate is always hydrated and the number of H₂O molecules is unknown or varies, while commercially available nickel(II) trifluoroacetylacetonate is dihydrated. In a preferred embodiment, the nickel containing compound is bis(2,2,6,6-tetramethyl-3,5-heptanedionato) nickel(II).

In embodiments, an oxygen-containing precursor is included in the gaseous mixture that is comprised of one or more carbonyl compounds. In specific embodiments, the carbonyl compound is an ester, and may further be an ester having an alkyl group with a β-hydrogen. The oxygen-containing precursor may be one or more of ethyl acetate, ethyl formate, ethyl propionate, isopropyl formate, isopropyl acetate, n-butyl acetate and t-butyl acetate. In a preferred embodiment, the oxygen-containing precursor is ethyl acetate.

In some embodiments, the gaseous mixture is comprised of molecular oxygen. In certain especially preferred embodiments, the gaseous mixture is comprised of a carbonyl compound, particularly ethyl acetate, and molecular oxygen.

In a particularly preferred embodiment, the gaseous mixture is comprised of bis(2,2,6,6-tetramethyl-3,5-heptanedionato) nickel(II), molecular oxygen, and ethyl acetate.

Preferably the ratio of oxygen to nickel in the nickel oxide coating is at least 0.5, more preferably at least 0.6, even more preferably at least 0.7, but preferably at most 1.2, more preferably at most 1.0, even more preferably at most 0.9. The ratio of oxygen to nickel in the nickel oxide coating may be measured by XPS.

Preferably the gaseous mixture comprises at least 0.3 vol % of the nickel-containing compound, more preferably at least 0.4 vol % of the nickel-containing compound, even more preferably at least 0.5 vol % of the nickel-containing compound, but preferably at most 5.0 vol % of the nickel-containing compound, more preferably at most 2.0 vol % of the nickel-containing compound, even more preferably at most 1.0 vol % of the nickel-containing compound.

Preferably the gaseous mixture comprises at least 3.0 vol % of the oxygen-containing precursor, more preferably at least 4.0 vol % of the oxygen-containing precursor, even more preferably at least 5.0 vol % of the oxygen-containing precursor, but preferably at most 20.0 vol % of the oxygen-containing precursor, more preferably at most 12.0 vol % of the oxygen-containing precursor, even more preferably at most 10.0 vol % of the oxygen-containing precursor.

### BRIEF DESCRIPTION OF THE DRAWING

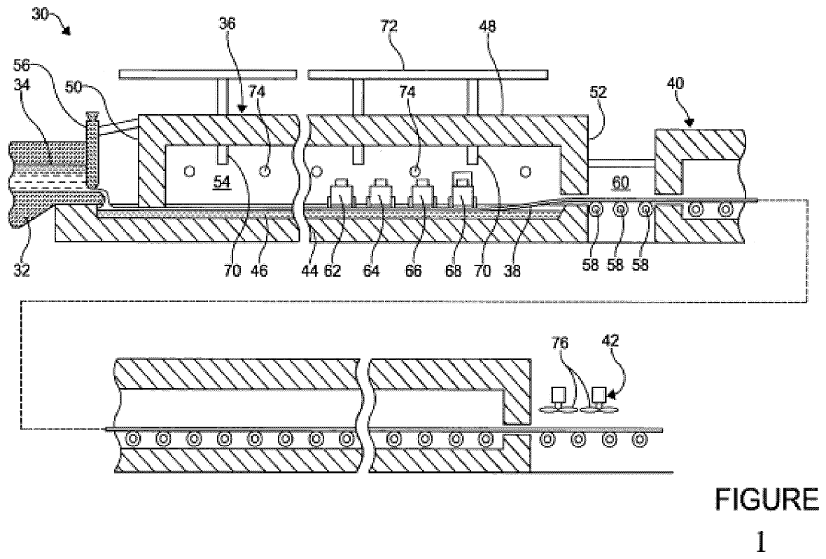

The above, as well as other advantages of the process will become readily apparent to those skilled in the art from the following detailed description when considered in the light of the accompanying drawings in which FIG. 1 is a schematic view, in vertical section, of an installation for practicing the float glass manufacturing process in accordance with an embodiment of the invention.

### DETAILED DESCRIPTION OF THE INVENTION

It is to be understood that the invention may assume various alternative orientations and step sequences, except where expressly specified to the contrary. It is also to be understood that the specific coated glass substrates, apparatuses and processes described in the following specification are simply exemplary embodiments of the inventive concepts. Hence, specific dimensions, directions, or other physical characteristics relating to the embodiments disclosed are not to be considered as limiting, unless expressly stated otherwise. Also, although they may not be, like elements in the various embodiments described within this section of the application may be commonly referred to with like reference numerals.

In the context of the present invention, where a layer or coating is said to be “based on” a particular material or materials, this means that the layer or coating predominantly consists of the corresponding said material or materials, which means typically that it comprises at least about 50 at. % of said material or materials.

In the following discussion of the invention, unless stated to the contrary, the disclosure of alternative values for the upper or lower limit of the permitted range of a parameter, coupled with an indication that one of said values is more highly preferred than the other, is to be construed as an implied statement that each intermediate value of said parameter, lying between the more preferred and the less preferred of said alternatives, is itself preferred to said less preferred value and also to each value lying between said less preferred value and said intermediate value.

Throughout this specification, the term “comprising” or “comprises” means including the component(s) specified but not to the exclusion of the presence of other components. The term “consisting essentially of” or “consists essentially of” means including the components specified but excluding other components except for materials present as impurities, unavoidable materials present as a result of processes used to provide the components, and components added for a purpose other than achieving the technical effect of the invention. Typically, when referring to compositions, a composition consisting essentially of a set of components will comprise less than 5% by weight, typically less than 3% by weight, more typically less than 1% by weight of non-specified components.

The term “consisting of” or “consists of” means including the components specified but excluding other components.

Whenever appropriate, depending upon the context, the use of the term “comprises” or “comprising” may also be taken to include the meaning “consists essentially of” or “consisting essentially of”, and also may also be taken to include the meaning “consists of” or “consisting of”.

References herein such as “in the range x to y” are meant to include the interpretation “from x to y” and so include the values x and y.

In the context of the present invention a transparent material or a transparent substrate is a material or a substrate that is capable of transmitting visible light so that objects or images situated beyond or behind said material can be distinctly seen through said material or substrate.

In the context of the present invention the “thickness” of a layer is, for any given location at a surface of the layer, represented by the distance through the layer, in the direction of the smallest dimension of the layer, from said location at a surface of the layer to a location at an opposing surface of said layer.

In the context of the present invention a “derivative” is a chemical substance related structurally to another chemical substance and theoretically derivable from it.

In an embodiment of the invention, a CVD process for forming a nickel oxide coating (hereinafter also referred to as the “CVD process”) is provided. The CVD process will be described in connection with a coated glass substrate. Such coated glass substrates may have many different applications. For example, and without limitation, the coated glass substrates may be utilized in solar cells, architectural glazings, electronics, and/or have automotive and aerospace applications. The coated glass substrates may be especially advantageous as a substrate in perovskite solar cells, with the NiOx serving as a buffer layer material.

The nickel oxide coating comprises nickel and oxygen. In certain embodiments, the nickel oxide coating may consist essentially of nickel and oxygen. The nickel oxide coating may also include a trace amount of one or more additional constituents such as, for example, carbon. As used herein, the phrase “trace amount” is an amount of a constituent of the layer based on nickel oxide that is less than 0.01 weight %, or equivalently, less than 100 ppm.

The CVD process may be carried out in conjunction with the manufacture of the glass substrate. In an embodiment, the glass substrate may be formed utilizing the well-known float glass manufacturing process. An example of a float glass manufacturing process is illustrated in FIG. 1. In this embodiment, the glass substrate may also be referred to as a glass ribbon. However, it should be appreciated that the CVD process can be utilized apart from the float glass manufacturing process or well after formation and cutting of the glass ribbon.

In certain embodiments, the CVD process is a dynamic deposition process. In these embodiments, the glass substrate is moving at the time of forming the nickel oxide coating. Preferably, the glass substrate moves at a predetermined rate of, for example, greater than 3.175 m/min (125 in/min) as the nickel oxide coating is being formed. In an embodiment, the glass substrate is moving at a rate of between 3.175 m/min (125 in/min) and 12.7 m/min (600 in/min) as the nickel oxide coating is being formed.

In certain embodiments, the glass substrate is heated. In an embodiment, the temperature of the glass substrate is about 1000° F. (538° C.) or more when the nickel oxide coating is formed. In another embodiment, the temperature of the glass substrate is between 1000° F. (538° C.) and 1400° F. (760° C.) when the nickel oxide coating is formed thereon.

Preferably, the nickel oxide coating is deposited over the deposition surface of the glass substrate while the surface is at essentially atmospheric pressure. In this embodiment, the CVD process is an atmospheric pressure CVD (APCVD) process. However, the CVD process is not limited to being an APCVD process as, in other embodiments, the nickel oxide coating may be formed under low-pressure conditions.

The glass substrate is not limited to any particular thickness. Also, the glass substrate may be of a conventional glass composition known in the art. In an embodiment, the glass substrate is a soda-lime-silica glass. In some embodiments, the substrate may be a portion of the float glass ribbon. However, the CVD process is not limited to a soda-lime-silica glass substrate as, in other embodiments, the glass substrate may be a borosilicate or aluminosilicate glass, as examples.

In addition, the transparency or absorption characteristics of the glass substrate may vary between embodiments. Further, the color of the glass substrate can vary between embodiments of CVD process. In an embodiment, the glass substrate may be substantially clear. In other embodiments, the glass substrate may be tinted or colored.

The nickel oxide coating may be deposited by providing one or more nickel-containing compounds selected from nickel(II) acetylacetonate and its derivatives, preferably one or more selected from the group consisting of nickel(II) acetylacetonate, bis(2,2,6,6-tetramethyl-3,5-heptanedionato) nickel(II), nickel(II) hexafluoroacetylacetonate, and nickel(II) trifluoroacetylacetonate, and one or more oxygen-containing molecules selected from the group consisting of a carbonyl compound and molecular oxygen.

Separate supply lines may extend from the sources of the reactant (precursor) molecules. As used herein, the phrases “reactant molecule” and “precursor molecule” may be used interchangeably to refer to any or all of the nickel-containing compounds and oxygen-containing molecules and/or used to describe the various embodiments thereof disclosed herein. Preferably, the sources of the precursor molecules are provided at a location outside a float bath chamber.

Preferably, the nickel oxide coating is deposited by forming a gaseous mixture. It is preferred that the precursor molecules used to form the gaseous mixture are suitable for use in a CVD process. Such molecules may at some point be a liquid or a solid but are volatile such that they can be vaporized for use in the gaseous mixture. In certain embodiments, the gaseous mixture includes precursor molecules suitable for forming the nickel oxide coating at essentially atmospheric pressure. Once in a gaseous state, the precursor molecules can be included in a gaseous stream and utilized to form the nickel oxide coating.

In some embodiments, the gaseous mixture formed to deposit the nickel oxide coating includes an oxygen-containing molecule comprised of a carbonyl compound. In these embodiments, the carbonyl compound is preferably an ester. More preferably, the carbonyl compound is an ester having an alkyl group with a β-hydrogen. Alkyl groups with a β-hydrogen containing two to ten carbon atoms are preferred. More preferably, the ester is selected from one or more of ethyl acetate (EtOAc), ethyl formate, ethyl propionate, isopropyl formate, isopropyl acetate, n-butyl acetate and t-butyl acetate. Most preferably, the oxygen-containing compound is ethyl acetate. In certain preferred embodiments, the gaseous mixture includes molecular oxygen in addition to a carbonyl compound such as ethyl acetate.

The gaseous mixture may also comprise one or more inert gases utilized as carrier or diluent gas. Suitable inert gases include nitrogen (N₂), helium (He), and mixtures thereof. Thus, sources of the one or more inert gases, from which separate supply lines may extend, may be provided.

The precursor molecules are mixed to form the gaseous mixture. In certain embodiments, a coating apparatus may be provided. Preferably, the gaseous mixture is fed through the coating apparatus before forming the nickel oxide coating on the glass substrate. The gaseous mixture may be discharged from the coating apparatus utilizing one or more gas distributor beams. Preferably, the gaseous mixture is formed prior to being fed through the coating apparatus. For example, the precursor molecules may be mixed in a feed line connected to an inlet of the coating apparatus. In other embodiments, the gaseous mixture may be formed within and before exiting the coating apparatus.

Preferably, the coating apparatus extends transversely across the glass substrate and is provided at a predetermined distance thereabove. The coating apparatus is preferably located at, at least, one predetermined location. When the CVD process is utilized in conjunction with the float glass manufacturing process, the coating apparatus is preferably provided within the float bath section thereof. However, the coating apparatus may be provided in the annealing lehr, and/or in the gap between the float bath and the annealing lehr.

The gaseous mixture is directed toward and along the glass substrate. Utilizing a coating apparatus aids in directing the gaseous mixture toward and along the glass substrate. Preferably, the gaseous mixture is directed toward and along the glass substrate in a laminar flow.

The gaseous mixture reacts at or near the glass substrate to form the nickel oxide coating thereover. In some embodiments, the nickel oxide coating is pyrolytic. As used herein, the term “pyrolytic” may refer to a coating that is chemically bonded to a glass substrate.

The nickel oxide coating of the invention may be formed over one or more previously deposited coatings. For example, the nickel oxide coating may be formed over a previously deposited silicon oxide coating, which was formed over a deposition surface of the glass substrate. The nickel oxide coating may be formed directly on the silicon oxide coating. In other embodiments, the nickel oxide coating may be formed over a previously deposited tin oxide coating, which was formed over the deposition surface of the glass substrate. In these embodiments, the tin oxide coating may be undoped or doped, and where the tin oxide coating is doped, it may be doped with fluorine. In some embodiments, the nickel oxide coating is formed over a TCO coating previously formed over the glass substrate. In certain preferred embodiments, the TCO is a coating based on tin oxide doped, for example, with fluorine. It may be preferred that the nickel oxide coating be deposited over a TCO coating that is deposited over a coating based on silicon oxide that is in turn deposited over the glass substrate. The nickel oxide coating may be formed directly on the tin oxide or other TCO coating. In certain embodiments, the nickel oxide coating is the outermost coating of a coating stack provided on a glass substrate.

In certain preferred embodiments, the glass substrate is provided with a coating stack comprising or, preferably, consisting of, in sequence from the deposition surface of the glass substrate, a coating based on silicon oxide, a coating based on tin oxide, and a coating based on nickel oxide. In these embodiments, the coating based on tin oxide may be doped or undoped.

In other preferred embodiments, the glass substrate is provided with a coating stack comprising or, preferably, consisting of, in sequence from the deposition surface of the glass substrate, a coating based on silicon oxide and a coating based on nickel oxide.

As discussed above, the nickel oxide coating may be formed in conjunction with the manufacture of the glass substrate in the well-known float glass manufacturing process. The float glass manufacturing process is typically carried out utilizing a float glass installation, such as the installation 30 depicted in FIG. 1. However, it should be understood that the float glass installation 30 described herein is only illustrative of such installations.

As illustrated in FIG. 1, the float glass installation 30 may comprise a canal section 32 along which molten glass 34 is delivered from a melting furnace, to a float bath section 36 where the glass substrate is formed. In this embodiment, the glass substrate will be referred to as a glass ribbon 38. The glass ribbon 38 is a preferable substrate over which the nickel oxide coating is formed. However, it should be appreciated that the glass substrate is not limited to being a glass ribbon.

In embodiments of the invention, the glass ribbon 38 advances from the bath section 36 through an adjacent annealing lehr 40 and a cooling section 42. The float bath section 36 includes: a bottom section 44 within which a bath of molten tin 46 is contained, a roof 48, opposite side walls (not depicted) and end walls 50, 52. The roof 48, side walls and end walls 50, 52 together define an enclosure 54 in which a non-oxidizing atmosphere is maintained to prevent oxidation of the molten tin 46.

In operation, the molten glass 34 flows along the canal 32 beneath a regulating tweel 56 and downwardly onto the surface of the tin bath 46 in controlled amounts. On the molten tin surface, the molten glass 34 spreads laterally under the influence of gravity and surface tension, as well as certain mechanical influences, and it is advanced across the tin bath 46 to form the glass ribbon 38. The glass ribbon 38 is removed from the bath section 36 over lift out rolls 58 and is thereafter conveyed through the annealing lehr 40 and the cooling section 42 on aligned rolls. The deposition of the nickel oxide coating preferably takes place in the float bath section 36, although it may be possible for deposition to take place further along the glass production line, for example, in the gap 60 between the float bath 36 and the annealing lehr 40, or in the annealing lehr 40.

As illustrated in FIG. 1, a coating apparatus 62 is shown within the float bath section 36. The nickel oxide coating may be formed utilizing the coating apparatus 62. In this embodiment, the nickel oxide coating may be formed directly on the glass substrate. In certain embodiments, the nickel oxide coating may be formed over one or more coatings previously formed on the glass ribbon 38. Each of these coatings may be formed utilizing a separate coating apparatus. For example, in an embodiment, a coating layer comprising silicon oxide may be deposited utilizing coating apparatus 62, 64. In this embodiment, the nickel oxide coating may be formed directly on or over the silicon oxide coating utilizing another coating apparatus, which is positioned downstream of the coating apparatus 62, 64 utilized to form the tin oxide coating, provided in the float bath section 36 or in another portion of the float glass installation 30 as described above. In another embodiment, a coating apparatus 66 may be provided and utilized to form a coating that comprises fluorine doped tin oxide. In this embodiment, the nickel oxide coating may be formed directly on or over the doped tin oxide coating utilizing a coating apparatus 68 positioned downstream of the coating apparatus 66.

A suitable non-oxidizing atmosphere, generally nitrogen or a mixture of nitrogen and hydrogen in which nitrogen predominates, is maintained in the float bath section 36 to prevent oxidation of the molten tin 46 comprising the float bath. The atmosphere gas is admitted through conduits 70 operably coupled to a distribution manifold 72. The non-oxidizing gas is introduced at a rate sufficient to compensate for normal losses and maintain a slight positive pressure, on the order of between about 0.001 and about 0.01 atmosphere above ambient atmospheric pressure, so as to prevent infiltration of outside atmosphere. For purposes of describing the invention, the above-noted pressure range is considered to constitute normal atmospheric pressure.

Preferably, the nickel oxide coating is formed at essentially atmospheric pressure. Thus, the pressure of the float bath section 36, annealing lehr 40, and/or in the gap 60 between the float bath section 36 and the annealing lehr 40 may be essentially atmospheric pressure.

Heat for maintaining the desired temperature regime in the float bath section 36 and the enclosure 54 may be provided by radiant heaters 74 within the enclosure 54. The atmosphere within the lehr 40 is typically atmospheric air, as the cooling section 42 is not enclosed and the glass ribbon 38 is therefore open to the ambient atmosphere. The glass ribbon 38 is subsequently allowed to cool to ambient temperature. To cool the glass ribbon 38, ambient air may be directed against the glass ribbon 38 as by fans 76 in the cooling section 42. Heaters (not depicted) may also be provided within the annealing lehr 40 for causing the temperature of the glass ribbon 38 to be gradually reduced in accordance with a predetermined regime as it is conveyed therethrough.

### EXAMPLES

The following examples are presented solely for the purpose of further illustrating and disclosing embodiments of the process for depositing a nickel oxide coating in accordance with the invention, and are not to be construed as a limitation on the invention.

Example 1 is the deposition of a nickel oxide coating deposited on a lab coater directly on a pyrolytic silicon oxide coating previously formed on a glass substrate. The glass substrate was of the soda-lime-silica variety, had a thickness of 3.2 mm, and was moving at the time the nickel oxide coating was deposited thereon at a line speed of 75 in./min. The nickel oxide coating was deposited by forming a gaseous mixture of bis(2,2,6,6-tetramethyl-3,5-heptanedionato) nickel(II) and molecular oxygen. The bis(2,2,6,6-tetramethyl-3,5-heptanedionato) nickel(II) was provided as 20 wt. % in a trimethylamine solution at a flow rate of 18.0 cc/min. These precursors were mixed to form a gaseous mixture and then fed through the lab coating apparatus before being directed toward and along the glass substrate. The estimated gas phase concentrations were 0.50 vol % for the bis(2,2,6,6-tetramethyl-3,5-heptanedionato) nickel(II) and 5.00 vol % for the molecular oxygen, with the balance being nitrogen. A uniform coating of nickel oxide was formed over the glass substrate at a deposition rate of about 1.5 nm/sec., the coating having a thickness determined by scanning electron microscope (SEM) of 100 Å. The ratio of oxygen to nickel in the coating was measured by X-ray photoelectron spectroscopy (XPS) to be 0.7. The coated glass substrate of Example 1 was measured as having a transmission of light of 90.76% and a film side reflectance of 8.23%. The light transmission and film side reflectance were measured in each example with a UV-Vis-NIR spectrometer for wavelengths of 380 nm to 780 nm.

Example 2 is the deposition of a nickel oxide coating deposited on a lab coater directly on a pyrolytic silicon oxide coating previously formed on a glass substrate. The glass substrate was of the soda-lime-silica variety, had a thickness of 3.2 mm, and was moving at the time the nickel oxide coating was deposited thereon at a line speed of 75 in./min. The nickel oxide coating was deposited by forming a gaseous mixture of bis(2,2,6,6-tetramethyl-3,5-heptanedionato) nickel(II), ethyl acetate, and molecular oxygen. The bis(2,2,6,6-tetramethyl-3,5-heptanedionato) nickel(II) was provided as 20 wt. % in a trimethylamine solution at a flow rate of 18.0 cc/min. These precursors were mixed to form a gaseous mixture and then fed through the lab coating apparatus before being directed toward and along the glass substrate. The estimated gas phase concentrations were 0.50 vol % for the bis(2,2,6,6-tetramethyl-3,5-heptanedionato) nickel(II), 5.00 vol % for the ethyl acetate, and 5.00 vol % for the molecular oxygen, with the balance being nitrogen. A uniform coating of nickel oxide was formed over the glass substrate, the coating having a thickness determined by SEM of 100 Å. The ratio of oxygen to nickel in the coating was measured by XPS to be 0.7. The coated glass substrate of Example 2 was measured as having a transmission of light of 91.21% and a film side reflectance of 8.11%.

Example 3 is the deposition of a nickel oxide coating deposited using a lab coater on a coated glass substrate commercially available from Nippon Sheet Glass Co., Ltd. as NSG TEC 15™. The substrate thus had the following layers: glass/SiO₂/SnO₂/SnO₂:F, and the nickel oxide coating was deposited directly on a pyrolytic fluorine doped tin oxide coating previously formed on a glass substrate. The glass substrate was of the soda-lime-silica variety, had a thickness of 3.2 mm, and was moving at the time the nickel oxide coating was deposited thereon at a line speed of 75 in./min. The nickel oxide coating was deposited by forming a gaseous mixture of bis(2,2,6,6-tetramethyl-3,5-heptanedionato) nickel(II) and molecular oxygen. The bis(2,2,6,6-tetramethyl-3,5-heptanedionato) nickel(II) was provided as 20 wt. % in a trimethylamine solution at a flow rate of 18.0 cc/min. These precursors were mixed to form a gaseous mixture and then fed through the lab coating apparatus before being directed toward and along the glass substrate. The estimated gas phase concentrations were 0.50 vol % for the bis(2,2,6,6-tetramethyl-3,5-heptanedionato) nickel(II) and 5.00 vol % for the molecular oxygen, with the balance being nitrogen. A discontinuous coating of nickel oxide was formed over the glass substrate. The coated glass substrate of Example 3 was measured as having a transmission of light of 83.92% and a film side reflectance of 11.72%.

Example 4 is the deposition of a nickel oxide coating deposited on a lab coater directly on a pyrolytic silicon oxide coating previously formed on a glass substrate. The glass substrate was of the soda-lime-silica variety, had a thickness of 3.2 mm, and was static during the 15 second deposition. The nickel oxide coating was deposited by forming a gaseous mixture of bis(2,2,6,6-tetramethyl-3,5-heptanedionato) nickel(II), ethyl acetate, and molecular oxygen. The bis(2,2,6,6-tetramethyl-3,5-heptanedionato) nickel(II) was provided as 20 wt. % in a trimethylamine solution at a flow rate of 18.0 cc/min. These precursors were mixed to form a gaseous mixture and then fed through the lab coating apparatus before being directed toward and along the glass substrate. The estimated gas phase concentrations were 0.80 vol % for the bis(2,2,6,6-tetramethyl-3,5-heptanedionato) nickel(II), 5.00 vol % for the ethyl acetate, and 5.00 vol % for the molecular oxygen, with the balance being nitrogen. A uniform coating of nickel oxide was formed over the glass substrate, the coating having a thickness determined by optical modeling of 300 Å. The ratio of oxygen to nickel in the coating was measured by XPS to be 0.8. The coated glass substrate of Example 3 was measured as having a transmission of light of 71.43% and a film side reflectance of 26.05%.

The foregoing description is considered as illustrative only of the principles of the invention. Further, since numerous modifications and changes will readily occur to those skilled in the art, it is not desired to limit the invention to the exact construction and processes shown and described herein. Accordingly, all suitable modifications and equivalents may be considered as falling within the scope of the invention.

1.-27. (canceled)

28. A chemical vapor deposition process for forming a nickel oxide coating over a glass substrate, comprising:
providing a glass substrate;
forming a gaseous mixture comprised of a nickel-containing compound selected from the group consisting of nickel(II) acetylacetonate and derivatives thereof, and an oxygen-containing precursor selected from the group consisting of a carbonyl compound and molecular oxygen;
directing the gaseous mixture toward and along the glass substrate; and
reacting the gaseous mixture over the glass substrate to form a coating of nickel oxide over the glass substrate.

29. The chemical vapor deposition process defined in claim 28, wherein the nickel-containing compound is selected from the group consisting of nickel(II) acetylacetonate, bis(2,2,6,6-tetramethyl-3,5-heptanedionato) nickel(II), nickel(II) hexafluoroacetylacetonate, and nickel(II) trifluoroacetylacetonate.

30. The chemical vapor deposition process defined in claim 28, wherein the nickel-containing compound is bis(2,2,6,6-tetramethyl-3,5-heptanedionato) nickel(II).

31. The chemical vapor deposition process defined in claim 28, wherein the oxygen-containing precursor is molecular oxygen.

32. The chemical vapor deposition process defined in claim 28, wherein the oxygen-containing precursor is a carbonyl compound.

33. The chemical vapor deposition process defined in claim 28, wherein the oxygen-containing precursor is an ester having an alkyl group with a β-hydrogen.

34. The chemical vapor deposition process defined in claim 28, wherein the oxygen-containing precursor is one or more of ethyl acetate, ethyl formate, ethyl propionate, isopropyl formate, isopropyl acetate, n-butyl acetate and t-butyl acetate.

35. The chemical vapor deposition process defined in claim 28, wherein the oxygen-containing precursor is ethyl acetate.

36. The chemical vapor deposition process defined in claim 28, wherein the gaseous mixture further comprises molecular oxygen.

37. The chemical vapor deposition process defined in claim 28, wherein the glass substrate is a glass ribbon in a float glass manufacturing process and/or wherein the ratio of oxygen to nickel in the nickel oxide coating is at least 0.5.

38. The chemical vapor deposition process defined in claim 28, further comprising providing a coating apparatus and feeding the gaseous mixture through the coating apparatus before forming the nickel oxide coating over the glass substrate and/or wherein the nickel oxide coating is formed on a deposition surface of the glass substrate which is at essentially atmospheric pressure when the gaseous mixture is reacted to form the nickel oxide coating.

39. The chemical vapor deposition process defined in claim 28, wherein the nickel oxide coating is formed over a coating previously formed on the glass substrate and/or wherein the nickel oxide coating is formed over a coating based on silicon oxide previously formed over the glass substrate.

40. The chemical vapor deposition process defined in claim 28, wherein the nickel oxide coating is formed over a coating based on tin oxide previously formed over the glass substrate, optionally wherein the coating based on tin oxide is doped with fluorine.

41. The chemical vapor deposition process defined in claim 28, wherein the nickel oxide coating is formed over a coating based on tin oxide that is formed over a coating based on silicon oxide that is in turn formed over the glass substrate and/or wherein the glass substrate is at a temperature of between 1000° F. (538° C.) and 1400° F. (760° C.) when the nickel oxide coating is formed thereover.

42. The chemical vapor deposition process defined by claim 28, wherein the nickel oxide coating is pyrolytic and/or wherein the nickel oxide coating is the outermost coating over a surface of the glass substrate.

43. The chemical vapor deposition process defined by claim 28, wherein the glass substrate is provided with a coating stack consisting of, in sequence from the glass substrate, a coating based on silicon oxide, a coating based on tin oxide, and the coating of nickel oxide.

44. The chemical vapor deposition process defined by claim 28, wherein the glass substrate is provided with a coating stack consisting of, in sequence from the glass substrate, a coating based on silicon oxide and the coating of nickel oxide.

45. The chemical vapor deposition process defined by claim 28, wherein the gaseous mixture comprises at least 0.3 vol % of the nickel-containing compound and/or wherein the gaseous mixture comprises at least 3.0 vol % of the oxygen-containing precursor.

46. A coated glass substrate formed in accordance with the chemical vapor deposition process defined by claim 28.

47. A perovskite solar cell utilizing a coated glass substrate as defined by claim 46 as a buffer layer.
